(19) United States
(12) Patent Application Publication
(10) Pub. No.: US 2014/0347643 A1
(43) Pub. Date: Nov. 27, 2014

(54) LITHOGRAPHY APPARATUS, LITHOGRAPHY METHOD, LITHOGRAPHY SYSTEM, AND METHOD OF MANUFACTURING ARTICLE

(71) Applicant: CANON KABUSHIKI KAISHA, Tokyo (JP)

(72) Inventors: Masashi KOTOKU, Tokyo (JP); Tomoyuki MIYASHITA, Utsunomiya-shi (JP); Hiromi KINEBUCHI, Utsunomiya-shi (JP)

(73) Assignee: CANON KABUSHIKI KAISHA, Tokyo (JP)

(21) Appl. No.: 14/283,264

(22) Filed: May 21, 2014

(30) Foreign Application Priority Data
May 23, 2013 (JP) 2013-109390

(51) Int. Cl. G03F 7/20

(52) U.S. Cl. CPC G03F 7/70558; G03F 7/2022
USPC 355/52; 430/322; 430/325

(57) ABSTRACT

The present invention provides a lithography apparatus which forms a pattern on a substrate, the apparatus including a first dosing device configured to apply a first dose to the substrate based on data corresponding to the pattern, an acquiring device configured to acquire information of an error of a dimension of a pattern formed on the substrate via application of the first dose thereto, and a second dosing device configured to apply a second dose to the substrate based on the acquired information.

### BACKGROUND OF THE INVENTION

1. Field of the Invention

The present invention relates to a lithography apparatus, a lithography method, a lithography system, and a method of manufacturing an article.

2. Description of the Related Art

Recent development of semiconductor manufacturing techniques boosts demands for further micropatterning and higher integration of circuit patterns.

To form such a micropattern, it is necessary to accurately manage the thickness of a resist (photosensitive agent) applied to a substrate by a resist coating apparatus, in addition to the resolution of a lithography apparatus. For example, in a most advanced process, a change of the resist thickness by only several nm greatly changes an exposure amount optimum for the thickness, impairing the uniformity of the pattern size (for example, line width). To coat a substrate with a resist uniformly with an error of smaller than several nm (that is, without thickness nonuniformity), an expensive resist coating apparatus is necessary.

When a spin coater is used as the resist coating apparatus, thickness nonuniformity hardly occurs in the circumferential direction (rotational direction) of a substrate structurally, but readily occurs in the radial direction of the substrate. When the substrate diameter is increased from 300 mm to 450 mm, it becomes further difficult to uniformly coat the substrate with the resist.

To solve this, Japanese Patent Laid-Open No. 2004-119570 has proposed a technique of measuring a resist thickness and calculating a correct exposure amount based on the measured resist thickness in a lithography apparatus.

However, the conventional technique has the following several problems. For example, a maskless drawing apparatus as one of lithography apparatuses draws a pattern on a substrate by blanking a charged particle beam without using a mask. This drawing apparatus controls the exposure amount by such blanking. When the drawing apparatus draws a 26 mm×33 mm pattern, the size of drawing data necessary to control the blanker is as very large as 15 TB or more for a 32-nm node and 30 TB or more for a 22-nm node.

For example, assume that the number of substrates processible by the drawing apparatus per hour is 10. When only the drawing time is considered without taking account of the overhead, drawing data needs to be transferred at a rate of 333 Gbps or higher for the 32-nm node and 667 Gbps or higher for the 22-nm node. This means a very heavy load on the drawing data processing system.

An increase in the size of drawing data along with micropatterning is unavoidable. To build a drawing apparatus (drawing data processing system) with a practical scale and cost, it is necessary to reduce the load on a process of drawing data, the load on transfer of drawing data, and the capacities of a logical device such as an ASIC or FPGA and a memory such as a DRAM. In terms of time, the error of the resist thickness needs to be reflected in drawing data in a short time until drawing actually starts after applying the resist to the substrate. However, the implementation of this is difficult unless the processing system has very high performance because the size of drawing data is enormous. In general, drawing data is held for each shot and repetitively used for respective shots. However, considering the size of drawing data, it is not practical due to time constraints to change (correct) and use drawing data for each shot. Note that the nonuniformity of the pattern dimension such as the line width on the substrate may arise not only from the resist thickness distribution, but also from various causes such as nonuniformity, on the substrate, of the condition of a process (for example, development) to be performed on the resist.

### SUMMARY OF THE INVENTION

The present invention provides a lithography apparatus advantageous in terms of precision of patterning a substrate.

According to one aspect Of the present invention, there is provided a lithography apparatus which forms a pattern on a substrate, the apparatus including a first dosing device configured to apply a first dose to the substrate based on data corresponding to the pattern, an acquiring device configured to acquire information of an error of a dimension of a pattern formed on the substrate via application of the first dose thereto, and a second dosing device configured to apply a second dose to the substrate based on the acquired information.

Further aspects of the present invention will become apparent from the following description of exemplary embodiments with reference to the attached drawings.

### BRIEF DESCRIPTION OF THE DRAWINGS

FIG. 1 is a flowchart for explaining an example of a lithography method as one aspect of the present invention.

FIG. 2 is a flowchart for explaining an example of a lithography method as one aspect of the present invention.

FIG. 3 is a flowchart for explaining an example of is lithography method as one aspect of the present invention.

FIG. 4 is a schematic view showing the arrangement of a lithography apparatus as one aspect of the present invention.

FIG. 5 is a view showing an example of the arrangement of a lithography system including the lithography apparatus shown in FIG. 4, and an external apparatus.

FIG. 6 is a chart showing an example of transfer of a substrate between respective units in the lithography system shown in FIG. 5, and an example of the sequence of processes in the respective units.

FIG. 7 is a chart showing an example of transfer of a substrate between respective units in the lithography system shown in FIG. 5, and an example of the sequence of processes in the respective units.

FIG. 8 is a view showing an example of the arrangement of a lithography system as one aspect of the present invention.

### DESCRIPTION OF THE EMBODIMENTS

Preferred embodiments Of the present invention will be described below with reference to the accompanying drawings. Note that the same reference numerals denote the same members throughout the drawings, and a repetitive description thereof will not be given.

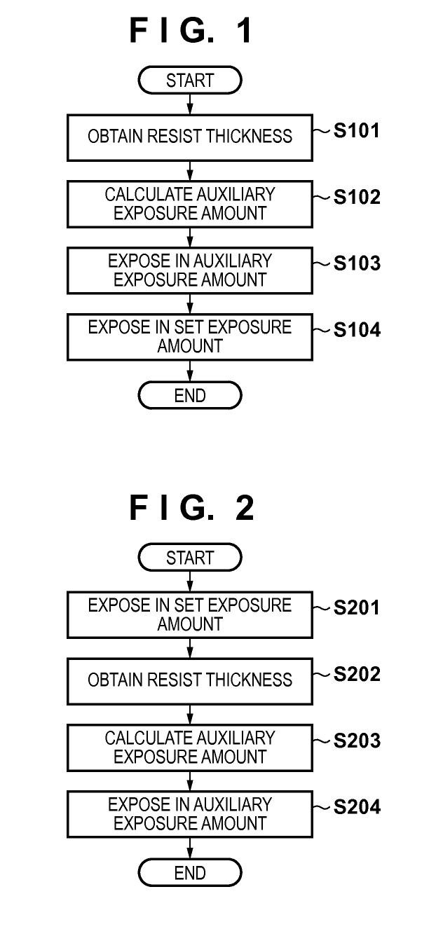

A lithography method will be described as one aspect of the present invention with reference to FIGS. 1 to 3. The lithography method according to an embodiment is, for example, a method which is used in the manufacture of a semiconductor device in order to form a pattern on a substrate.

In step S101, the thickness of a resist (photosensitive agent) applied to a substrate is obtained. More specifically, the thickness of the resist applied to the substrate is measured to obtain the thickness distribution of the resist within the substrate surface.

In step S102, an auxiliary exposure amount for a set exposure amount (exposure amount is also called a dose) set in advance to form a pattern is calculated for each of a plurality of positions on the substrate based on the resist thickness (thickness distribution) obtained in step S101. More specifically, an auxiliary exposure amount distribution within the substrate surface that corresponds to the resist thickness distribution is calculated. Note that the exposure amount is given not only to light (beam), but also to any energy line such as a charged particle beam as long as it forms a latent image on the resist.

In step S103, the substrate coated with the resist is exposed based on the auxiliary exposure amount calculated in step S102. More specifically, each of the plurality of positions on the substrate is exposed in the auxiliary exposure amount calculated in step S102 (that is, the substrate is exposed so that the exposure amount distribution on the substrate becomes the calculated auxiliary exposure amount distribution).

In step S104, the substrate coated with the resist is exposed based on the set exposure amount set in advance to form a pattern. More specifically, each of the plurality of positions on the substrate is exposed in the set exposure amount, thereby forming (drawing) a pattern on the substrate.

However, the order of steps S101 to S104 is not limited to the order shown in FIG. 1. For example, as shown in FIG. 2, each of the plurality of positions on the substrate may be exposed in the set exposure amount set in advance to form a pattern, before being exposed in the auxiliary exposure amount. Referring to FIG. 2, in step S201, a substrate coated with a resist is exposed based on a set exposure amount set in advance to form a pattern. In step S202, the thickness (thickness distribution) of the resist applied to the substrate is obtained. In step S203, an auxiliary exposure amount (auxiliary exposure amount distribution) to be added to the set exposure amount is calculated for each of a plurality of positions on the substrate based on the resist thickness obtained in step S202. In step S204, the substrate coated with the resist is exposed based on the auxiliary exposure amount calculated in step S203.

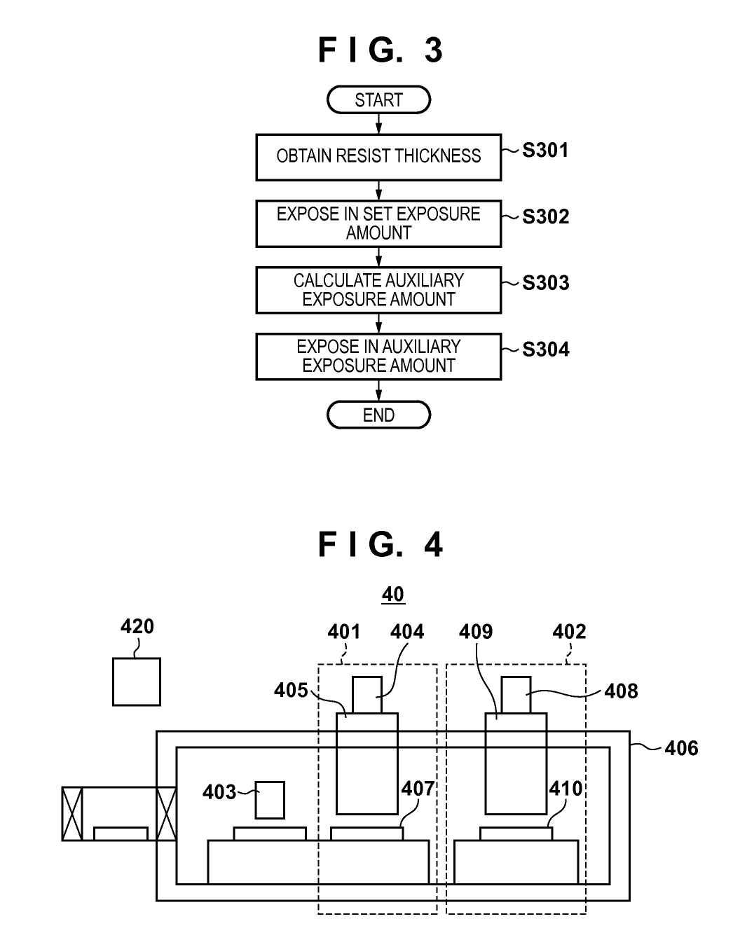

It is also possible to obtain the thickness of a resist applied to a substrate, then expose each of a plurality of positions on the substrate in a set exposure amount set in advance to form a pattern, and further expose it in an auxiliary exposure amount, as shown in FIG. 3. Referring to FIG. 3, in step S301, the thickness (thickness distribution) of a resist applied to a substrate is obtained. In step S302, the substrate coated with the resist is exposed based on a set exposure amount set in advance to form a pattern. In step S303, an auxiliary exposure amount (auxiliary exposure amount distribution) to be added to the set exposure amount is calculated for each of a plurality of positions on the substrate based on the resist thickness obtained in step S302. In step S304, the substrate coated with the resist is exposed based on the auxiliary exposure amount calculated in step S303. However, the process in step S303 may be performed before the process in step S302.

FIG. 4 is a schematic view showing the arrangement of a lithography apparatus 400 as one aspect of the present invention. The lithography apparatus 400 is an apparatus which forms a pattern on a substrate, and performs the respective processes of the lithography methods shown in FIGS. 1 to 3. The following description assumes that the lithography apparatus 400 performs the respective processes of the lithography method shown in FIG. 2. The lithography apparatus 400 includes a first exposure unit 401 which exposes each of a plurality of positions on a substrate in an auxiliary exposure amount, and a second exposure unit 402 which exposes each of the plurality of positions on the substrate in a preset exposure amount. The lithography apparatus 400 includes a measurement unit 403, and a control unit 420 which includes a CPU and memory and controls the overall (operation of) lithography apparatus 400. The second exposure unit 402 functions as the first dosing device configured to apply the first dose to a substrate based on data corresponding to a pattern. The first exposure unit 401 functions as the second dosing device configured to apply the second dose to the substrate based on information about the error of the dimension of the pattern formed through the application of the first dose.

In the embodiment, the first exposure unit 401 and second exposure unit 402 are constructed as a drawing apparatus which exposes a substrate using a charged particle beam (that is, performs drawing on a substrate by a charged particle beam). The drawing unit (first interval) when the first exposure unit 401 draws a pattern on a substrate is set to be larger than the drawing unit (second interval) when the second exposure unit 402 draws a pattern on a substrate. However, the construction of the first exposure unit 401 and second exposure unit 402 is not limited to the drawing apparatus. It is only necessary that a grid on a substrate in exposure by the first exposure unit 401 is larger than a grid on the substrate in exposure by the second exposure unit 402. For example, the first exposure unit 401 may be constructed as an exposure apparatus or imprint apparatus which exposes a substrate at once using light, and the second exposure unit 402 may be constructed as a drawing apparatus which exposes a substrate for each grid using a charged particle beam.

The measurement unit 403 is a thickness measurement device which measures the thickness of a resist applied to a substrate. The measurement unit 403 is constructed by, for example, a spectral interference reflectance measurement device. The measurement unit 403 functions as an acquiring device configured to obtain (acquire) to resist thickness as information about a resist applied to a substrate.

The measurement unit 403 measures a resist thickness at each of a plurality of positions on a substrate loaded into the lithography apparatus 400, and generates the resist thickness distribution within the substrate surface. The interval to measure a resist thickness is set to be, for example, several mm. When the spatial frequency of resist thickness nonuniformity is higher than the number of measurement points, this interval is set to be smaller than several mm in accordance with the performance of a resist coating apparatus (for example, spin coater).

The control unit 420 functions as a processing unit configured to obtain, for each of a plurality of positions on a substrate based on a resist thickness measured by the measurement unit 403, an auxiliary exposure amount to be added to a set exposure amount set in advance to form a pattern. More specifically, first, by looking up a calculation equation, table, or the like, the control unit 420 obtains an exposure amount necessary to form a pattern of a predetermined dimension at a resist thickness measured by the measurement unit 403. The calculation equation or table is appropriately selected in accordance with the type and sensitivity of the resist, the underlying material, and the like. Then, the control unit 420 obtains an exposure amount as an auxiliary exposure amount by subtracting, from the obtained first exposure amount, the set exposure amount necessary to form a pattern of a predetermined dimension when the resist thickness has a designed value. The set exposure amount is an exposure amount at which the second exposure unit 402 irradiates a substrate. The auxiliary exposure amount may be obtained in consideration of a post-exposure delay till development after the resist is irradiated with a charged particle beam.

When the set exposure amount is subtracted from the first exposure amount in obtaining an auxiliary exposure amount, the exposure amount may become negative (negative value), that is, the actual thickness of a resist applied to a substrate may be smaller than a designed value. In such a case, it suffices to set the auxiliary exposure amount to be 0 for a position at which the exposure amount becomes negative upon subtracting the set exposure amount from the first exposure amount, out of a plurality of positions on a substrate. It is also possible to notify the second exposure unit 402 of a position at which the exposure amount becomes negative upon subtracting the set exposure amount from the first exposure amount, and to correct the set exposure amount by the second exposure unit 402. Alternatively, the resist coating apparatus may apply a resist to a substrate so that the smallest resist thickness becomes equal to or larger than the designed value in consideration of resist thickness nonuniformity to prevent the actual thickness of the resist applied to the substrate from becoming smaller than the designed value.

The first exposure unit 401 irradiates a substrate coated with a resist, with a charged particle beam such as an electron beam or ion beam in a vacuum environment in accordance with the auxiliary exposure amount (auxiliary exposure amount distribution). The exposure (auxiliary exposure) in the first exposure unit 401 aims to correct resist thickness nonuniformity, and no micropatterning is requested. In the embodiment, therefore, the first exposure unit 401 draws a large region at once on a substrate to shorten the time taken for auxiliary exposure.

Details of the arrangement of the first exposure unit 401 will be explained. A charged particle beam from a charged particle source 404 irradiates a substrate held on a substrate stage 407 arranged in the internal space of a vacuum chamber 406 via a charged particle optical system 405. The charged particle optical system 405 includes, for example, a first shaping aperture, a shaping deflector, a second shaping aperture, a charged particle lens which converges a charged particle beam, a blanking mechanism which cuts off irradiation of a charged particle beam to a region other than a region to undergo drawing, and a deflector which adjusts the position of a charged particle beam.

The resist coating apparatus more readily causes resist thickness nonuniformity in the radial direction than in the circumferential direction because it applies a resist while rotating a substrate. Considering this, the first exposure unit 401 employs a vector scanning (λθ) drawing method (polar coordinate beam scanning method) which can change the exposure amount more easily in the radial direction of a substrate than in the circumferential direction.

The second exposure unit 402 irradiates the substrate having undergone auxiliary exposure by the first exposure unit 401, with a charged particle beam such as an electron beam or ion beam in a vacuum environment in accordance with the set exposure amount. The exposure in the second exposure unit 402 aims to quickly draw a micropattern. Thus, the second exposure unit 402 is constructed by a so-called multi-beam drawing apparatus which performs drawing using a plurality of charged particle beams.

Details of the arrangement of the second exposure unit 402 will be explained. A charged particle beam from a charged particle source 408 irradiates a substrate held on a substrate stage 410 arranged in the internal space of the vacuum chamber 406 via a charged particle optical system 409. The charged particle optical system 409 includes, for example, a charged particle lens which converges a charged particle beam, a blanking mechanism which cuts off irradiation of a charged particle beam to a region other than a region to undergo drawing, and a deflector which adjusts the position of a charged particle beam.

In this manner, the lithography apparatus 400 exposes each of a plurality of positions on a substrate in an auxiliary exposure amount based on the thickness distribution of a resist applied to the substrate. The lithography apparatus 400 can therefore form (draw) a pattern of a predetermined dimension on the substrate at high accuracy regardless of thickness nonuniformity of a resist applied to the substrate. Note that the substrate on which the pattern has been formed by the lithography apparatus 400 is transported to an apparatus (for example, development apparatus) which performs the next step.

In the lithography apparatus 400, after the first exposure unit 401 exposes a substrate in an auxiliary exposure amount, the second exposure unit 402 exposes the substrate in a set exposure amount. Alternatively, after the second exposure unit 402 exposes a substrate in a set exposure amount, the first exposure unit 401 may expose the substrate in an auxiliary exposure amount.

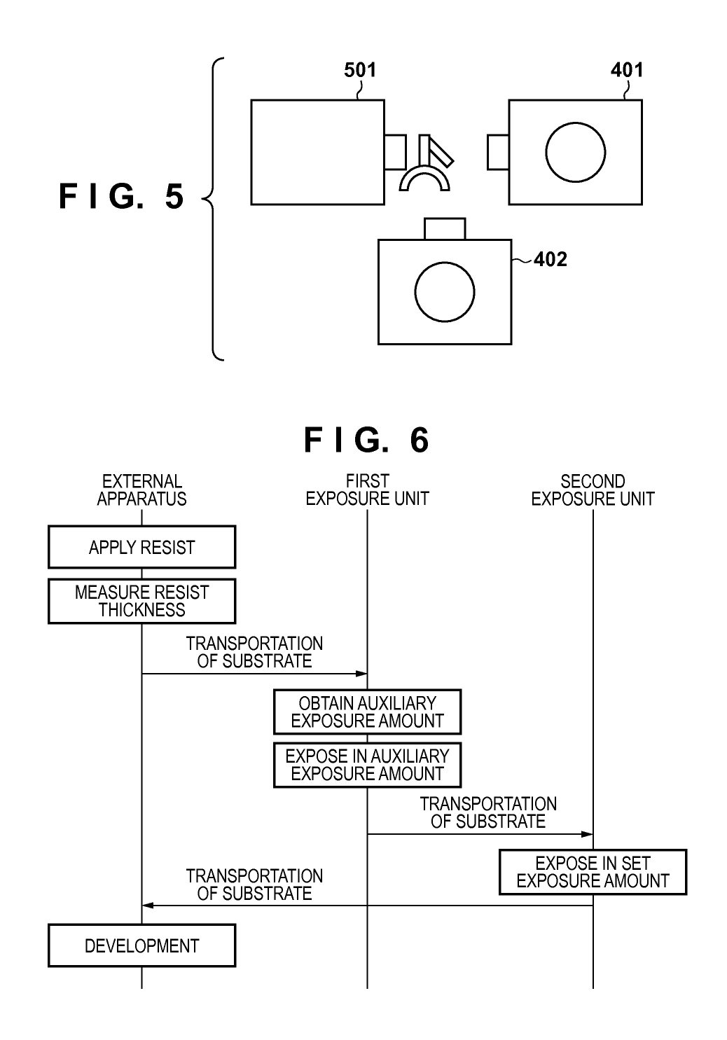

FIG. 5 is a view showing an example of the arrangement of a lithography system including the lithography apparatus 400 shown in FIG. 4, more specifically, the first exposure unit 401 and second exposure unit 402, and an external apparatus 501 such as a resist coating apparatus or development apparatus (developer). FIG. 6 is a chart showing an example of transfer of a substrate between the respective units in the lithography system shown in FIG. 5, and an example of the sequence of processes in the respective units. Assume that the external apparatus 501 has a function of measuring the thickness of a resist applied to a substrate. However, the measurement unit 403 of the lithography apparatus 400 can also measure the thickness of a resist applied to a substrate, as described above.

Referring to FIGS. 5 and 6, a substrate is loaded into the external apparatus 501, and the external apparatus 501 applies a resist to the substrate. Then, the external apparatus 501 measures the thickness (thickness distribution) of the resist applied to the substrate. The measured resist thickness distribution is input to the first exposure unit 401 and control unit 420 as information associated with the substrate having this thickness distribution. The substrate whose resist thickness has been measured by the external apparatus 501 is transported to the first exposure unit 401.

Upon receiving the substrate transported from the external apparatus 501, the first exposure unit 401 obtains, from the control unit 420, an auxiliary exposure amount (auxiliary exposure amount to be added, for each of a plurality of positions on a substrate, to a set exposure amount set in advance to form a pattern) corresponding to the transported substrate. Then, the first exposure unit 401 exposes (auxiliary exposure) each of the plurality of positions on the substrate in the auxiliary exposure amount. The substrate having undergone auxiliary exposure by the first exposure unit 401 is transported to the second exposure unit 402.

Upon receiving the substrate transported from the first exposure unit 401, the second exposure unit 402 obtains a set exposure amount corresponding to the transported substrate. Then, the second exposure unit 402 exposes each of the plurality of positions on the substrate in the set exposure amount. The substrate exposed by the second exposure unit 402 is transported to the external apparatus 501.

Upon receiving the substrate transported from the second exposure unit 402, the external apparatus 501 develops the transported substrate.

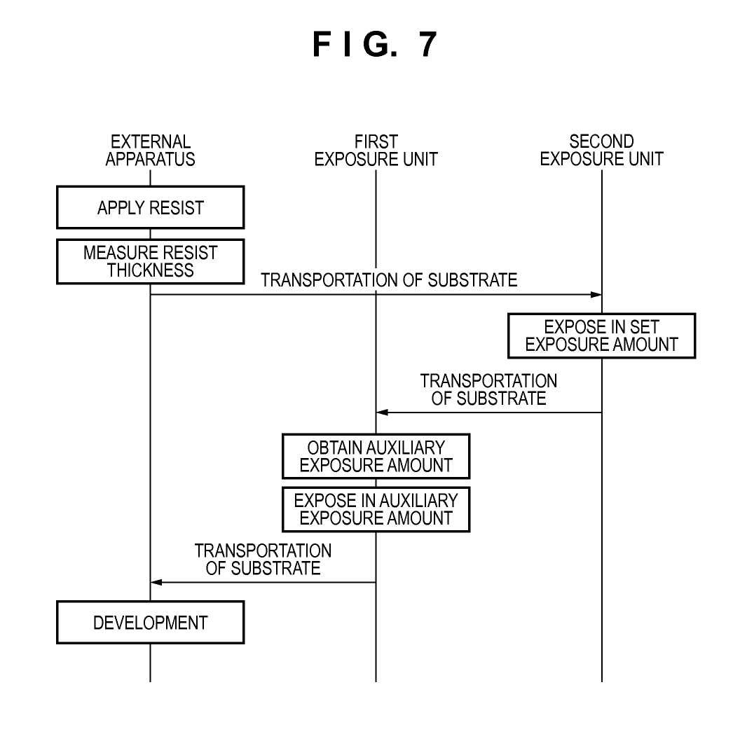

In FIG. 6, after the first exposure unit 401 exposes the substrate in the auxiliary exposure amount, the second exposure unit 402 exposes it in the set exposure amount. Alternatively, after the second exposure unit 402 exposes the substrate in the set exposure amount, the first exposure unit 401 may expose the substrate in the auxiliary exposure amount, as shown in FIG. 7.

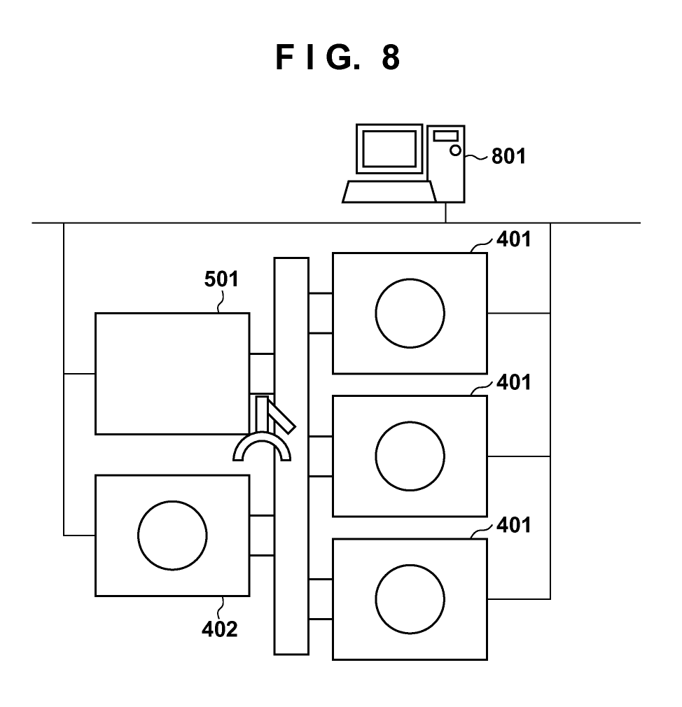

FIG. 8 is a view showing an example of the arrangement of a lithography system including a plurality of first exposure units (first lithography apparatuses) 401, the second exposure unit (second lithography apparatus) 402, the external apparatus 501 such as a resist coating apparatus or development apparatus (developer), and a control apparatus 801. In the lithography system shown in FIG. 8, the plurality of first exposure units 401, the second exposure unit 402, and the external apparatus 501 construct a cluster.

In the lithography system shown in FIG. 8, each of the plurality of first exposure units 401 may include the above-described measurement unit 403 and control unit 420. However, clustering greatly complicates management, in each first exposure unit 401, of the auxiliary exposure amount of each substrate, information representing a substrate having undergone auxiliary exposure and a substrate not having undergone auxiliary exposure among substrates loaded into the cluster, and the like. To solve this, the lithography system shown in FIG. 8 includes the control apparatus 801 which manages them. The control apparatus 801 controls the first exposure units 401 and the second exposure unit 402 in accordance with the process status of each of the plurality of first exposure units 401 and that of the second exposure unit 402. For example, the control apparatus 801 selects one of the lithography methods shown in FIGS. 1 to 3 as a process to be performed by each first exposure unit 401 or the second exposure unit 402 so as to shorten the waiting times of the plurality of first exposure units 401 and that of the second exposure unit 402.

A factor which influences the dimension (line width) of a pattern to be formed on a substrate is not limited to thickness nonuniformity (thickness distribution) of a resist applied to the substrate. The factor also includes the conditions of various processes to be performed on the resist, such as the heating condition and development condition after forming the pattern. The auxiliary exposure amount may be obtained based on the conditions of various processes to be performed on the resist, instead of or in addition to the resist thickness. In other words, the auxiliary exposure amount may be obtained based on, as information about the resist (information about the error of the dimension of a pattern), at least one Of the resist thickness (measurement value) and the conditions of processes to be performed on the resist. Regardless of the factor, the auxiliary exposure amount may be obtained to compensate for the error of the line width of a pattern to be formed on a substrate. In this fashion, the auxiliary exposure amount may be obtained based on information about the auxiliary exposure amount (auxiliary exposure amount itself or information for obtaining the auxiliary exposure amount).

As described above, the lithography apparatus 400 and lithography system can form a pattern of a predetermined dimension on a substrate, and thus are suitable for manufacturing an article such as a microdevice (for example, a semiconductor device) or an element having a microstructure. The method of manufacturing an article will be explained by exemplifying a case in which the lithography apparatus 400 is used. However, the above-mentioned lithography system is also usable. The method of manufacturing an article includes a step of forming a pattern on a substrate using the lithography apparatus 400 (a step such as exposure, drawing, or imprint for adding energy to pattern a substrate, or a pattern regarding a mold or the like). The method of manufacturing an article also includes a step of processing the substrate on which the pattern has been formed by the preceding step (for example, a step of performing development or etching). Further, the manufacturing method can include other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-109390 filed on May 23, 2013, which is hereby incorporated by reference herein in its entirety.

What is claimed is:

1. A lithography apparatus which forms a pattern on a substrate, the apparatus comprising:
a first dosing device configured to apply a first dose to the substrate based on data corresponding to the pattern;
an acquiring device configured to acquire information of an error of a dimension of a pattern formed on the substrate via application of the first dose thereto; and
a second dosing device configured to apply a second dose to the substrate based on the acquired information.

2. The apparatus according claim 1, wherein the information includes information of at least one of a thickness of a resist on the substrate, and a condition of a process to be performed on the resist.

3. The apparatus according to claim 2, wherein the acquiring device includes a measurement device configured to measure the thickness.

4. The apparatus according to claim 1, wherein the information includes information of a measured value of the error.

5. The apparatus according to claim 1, further comprising a processor configured to obtain the second dose baaed on the information of the error.

6. The apparatus according to claim 5, wherein the processor is configured to obtain the second dose such that the second dose does not have a negative value.

7. The apparatus according to claim 1, wherein:
the first dosing device is configured to apply a dose to the substrate at a first interval thereon, and
the second dosing device is configured apply a dose to the substrate at a second interval, larger than the first interval, thereon.

8. The apparatus according to claim 1, wherein
the first dosing device is configured to apply a dose to the substrate with a charged particle beam, and
the second dosing device is configured to apply a dose to the substrate with light.

9. A lithography method of forming a pattern on a substrate, the method comprising steps of:
applying a first dose to the substrate based on data corresponding to the pattern;
acquiring information of an error of a dimension of a pattern formed on the substrate via application of the first dose thereto; and
applying a second dose to the substrate based on the acquired information.

10. A lithography system which forms a pattern on a substrate, the system comprising:
a first lithography apparatus configured to apply a first dose to the substrate based on data corresponding to the pattern;
an acquiring apparatus configured to acquire information of an error of a dimension of a pattern formed on the substrate via application of the first dose thereto; and
a second lithography apparatus configured to apply a second dose to the substrate based on the acquired information.

11. A method of manufacturing an article, the method comprising steps of:
forming a pattern on a substrate using a lithography apparatus;
developing the substrate on which the pattern has been formed; and
processing the developed substrate to manufacturing the article,
wherein the lithography apparatus forms the pattern on the substrate, and includes:
a first dosing device configured to apply a first dose to the substrate based on data corresponding to the pattern;
an acquiring device configured to acquire information of an error of a dimension of a pattern formed on the substrate via application of the first dose thereto; and
a second dosing device configured to apply a second dose to the substrate based on the acquired information.

12. A method of manufacturing an article, the method comprising:
forming a pattern on a substrate using a lithography system;
developing the substrate on which the pattern has been formed; and
processing the developed substrate to manufacturing the article,
wherein the lithography system forms the pattern on the substrate, and includes:
a first lithography apparatus configured to apply a first dose to the substrate based on data corresponding to the pattern;
an acquiring apparatus configured to acquire information of an error of a dimension of a pattern formed on the substrate via application of the first dose thereto; and
a second lithography apparatus configured to apply a second dose to the substrate based on the acquired information.
